(19) United States
(12) Patent Application Publication
(10) Pub. No.: US 2024/0192287 A1
(43) Pub. Date: Jun. 13, 2024

(54) METHOD FOR DETERMINING INTEGRITY FACTOR THROUGH MACHINE LEARNING, AND DEVICE FOR PERFORMING SUCH METHOD

(71) Applicant: ONEPREDICT CO., LTD., Seoul (KR)

(72) Inventors: Bo Seong SEO, Seoul (KR); Jae Kyung SHIN, Seoul (KR)

(21) Appl. No.: 18/554,298

(22) PCT Filed: Mar. 30, 2022
(86) PCT No.: PCT/KR2022/004541

§ 371 Date: Oct. 6, 2023

(30) Foreign Application Priority Data
Apr. 7, 2021 (KR) 10-2021-0045181

(51) Int. Cl. G01R 31/62; G01R 31/28

(52) U.S. Cl. CPC G01R 31/62; G01R 31/28

(57) ABSTRACT

A method for determining an integrity factor through machine learning, and a device for performing such a method can include the steps in which: a device status determination device determines an integrity feature on the basis of machine learning; the device state determination device generates an integrity plane on the basis of the integrity feature; the device state determination device receives target input data of a target device; the device state determination device determines an integrity factor corresponding to the target input data on the basis of the integrity plane; and the device status determination device determines the status of the target device on the basis of the integrity factor.

### BACKGROUND

### 1. Field of the Invention

The present invention relates to a method of determining an anomaly indicator through machine learning and an apparatus for performing the method. More specifically, the present invention relates to a method of determining an anomaly indicator through machine learning and an apparatus for performing the same that are capable of determining an anomaly indicator of a device, such as a transformer, through machine learning, and determining the state of the device.

### 2. Discussion of Related Art

With rapid industrial development, there is an increasing demand for electrical energy, leading to an increasing use of power transformers. Consequently, many of the currently installed transformers are aging, resulting in frequent unexpected facility accidents. As power transformers become larger and power systems become more complex, accidents caused by facility failures lead to widespread power outages, and disruptions in recovery and supply cause significant economic losses.

In order to minimize such losses, the current state of the transformer needs to be accurately diagnosed. Additionally, required operational maintenance needs to be performed to minimize unexpected transformer accidents.

Transformer accidents are mostly attributed to degradation of insulation strength. Transformer insulation breakdowns may be explosive in nature. The most effective method for analyzing insulation degradation characteristics mainly uses dissolved gas analysis (DGA). Organic insulating materials used in transformers, such as insulating oil and insulating paper, cause a temperature rise and local overheating due to operation.

In addition, thermal decomposition due to discharge or the like forms degradation byproducts including various gases. Among the degradation byproducts, gas is dissolved in insulating oil (oil). Accordingly, by regularly collecting the insulating oil of the transformer during operation and analyzing the concentration of the dissolved gas, it may be estimated whether there is an abnormality inside the transformer. However, when the state of the transformer is determined simply based on whether or not a criterion for a specific gas is exceeded or a pattern, it is difficult to accurately diagnose whether to perform maintenance or replacement of the transformer.

Therefore, research is needed on a method of more accurately diagnosing the causes of abnormalities in a transformer and the current state of the transformer.

### SUMMARY OF THE INVENTION

The present invention is directed to resolving the above described issues.

The present invention is directed to learning the state of a device based on machine learning, such as deep learning, and accurately determining the state of the device based on minimized anomaly features.

The present invention is directed to more accurately determining the state of a device corresponding to state indicator data located in a boundary area between states.

A representative configuration of the present invention for achieving the above objects is as follows.

According to an aspect of the present invention, there is provided a method of determining an anomaly indicator through machine learning comprises determining, by a device state determining apparatus, anomaly features based on machine learning, generating, by the device state determining apparatus, an anomaly plane based on the anomaly features, receiving, by the device state determining apparatus, target input data of a target device, determining, by the device state determining apparatus, an anomaly indicator corresponding to the target input data based on the anomaly plane and determining, by the device state determining apparatus, a state of the target device based on the anomaly indicator.

Meanwhile, the anomaly plane includes a plurality of pieces of state indicator data determined based on the machine learning, and the plurality of pieces of state indicator data are classified based on a decision boundary.

Further, the device state determining apparatus determines the state of the target device based on the decision boundary and a location of state indicator data (target input data) corresponding to the target input data on the anomaly plane.

According to another aspect of the present invention, there is provided a device state determining apparatus, which is an apparatus for determining an anomaly indicator through machine learning, the apparatus comprises a deep learning unit implemented to determine anomaly features based on machine learning, an anomaly plane generating unit configured to generate an anomaly plane based on the anomaly features, an input unit implemented to receive target input data of a target device, an anomaly indicator determining unit implemented to determine an anomaly indicator corresponding to the target input data based on the anomaly plane and a device state determining unit implemented to determine a state of the target device based on the anomaly indicator.

Meanwhile, the anomaly plane includes a plurality of pieces of state indicator data determined based on the machine learning, and the plurality of pieces of state indicator data are classified based on a decision boundary.

Further, the device state determining apparatus determines the state of the target device based on the decision boundary and a location of state indicator data (target input data) corresponding to the target input data on the anomaly plane.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a conceptual diagram illustrating a device state determining apparatus, which is capable of determining a state of a device, according to an embodiment of the present invention.

FIG. 2 discloses a method of generating an anomaly plane for determining the state of a device according to an embodiment according to the present invention.

FIG. 3 is a conceptual diagram showing a method of determining a first anomaly feature and a second anomaly feature according to an embodiment according to the present invention.

FIG. 4 discloses a method of classifying a transformer state based on an SVM according to an embodiment of the present invention.

FIG. 5 is a conceptual diagram showing a method of determining the state of a transformer through additional data classification for state indicator data (target input data) located in the boundary area according to an embodiment of the present invention.

### DETAILED DESCRIPTION OF EXEMPLARY EMBODIMENTS

The detailed description of the present invention will be made with reference to the accompanying drawings showing examples of specific embodiments of the present invention. These embodiments will be described in detail such that the present invention can be performed by those skilled in the art. It should be understood that various embodiments of the present invention are different but are not necessarily mutually exclusive. For example, a specific shape, structure, and characteristic of an embodiment described herein may be implemented in another embodiment without departing from the scope and spirit of the present invention. In addition, it should be understood that a position or arrangement of each component in each disclosed embodiment may be changed without departing from the scope and spirit of the present invention. Accordingly, there is no intent to limit the present invention to the detailed description to be described below. The scope of the present invention is defined by the appended claims and encompasses all equivalents that fall within the scope of the appended claims. Like reference numerals refer to the same or like elements throughout the description of the figures.

Hereinafter, in order to enable those skilled in the art to practice the present invention, exemplary embodiments of the present invention will be described in detail with reference to the accompanying drawings.

Conventional transformer diagnosis technology is a state determination technology based on a ratio of dissolved gas. For example, the Duval triangle quantifies the state of a transformer using a ratio of dissolved gas, and shows the severity of the transformer.

Hereinafter, the present invention discloses a method of extracting n-dimensional anomaly features through machine learning on multiple-dimension input data corresponding to information about a dissolved gas of a transformer, and determining the state of a device through an anomaly plane generated based on the n-dimensional anomaly features. In addition, the present invention discloses a method capable of, when determining a state of a device on an anomaly plane, more accurately determining the state of the device corresponding to anomaly indicator data located in a boundary area between states.

In the detailed description according to the present invention, for the sake of convenience of description, it is assumed that the device is a transformer, and the input data is dissolved gas data of the transformer. However, this is only an example, and the present invention may be applied to various other devices and various other types of input data, and the corresponding embodiments may also be included in the scope of the present invention.

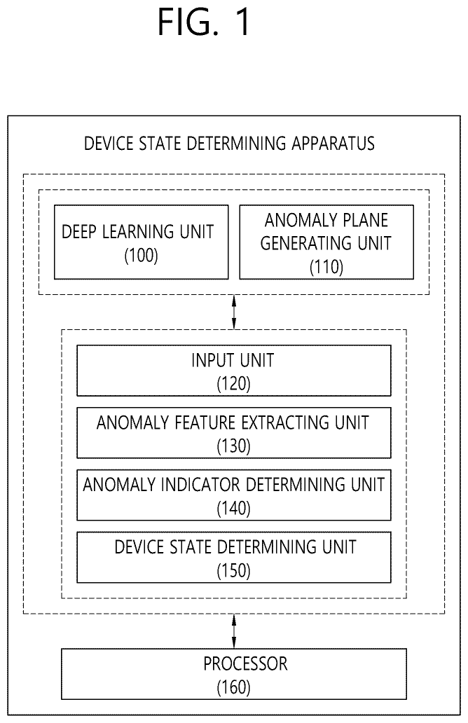

FIG. 1 is a conceptual diagram illustrating a device state determining apparatus, which is capable of determining a state of a device, according to an embodiment of the present invention.

In FIG. 1, the device state determining apparatus that is implemented to determine an anomaly indicator through a trained model based on deep learning and determine the state of a transformer based on the anomaly indicator is disclosed.

Referring to FIG. 1, the device state determining apparatus may include a deep learning training unit 100, an anomaly plane generating unit 110, an input unit 120, an anomaly feature extracting unit 130, an anomaly indicator determining unit 140, a device state determining unit 150, and a processor 160.

The deep learning unit 100 may be implemented to receive input data for learning and determine a first anomaly feature and a second anomaly feature for generating an anomaly plane. For example, the deep learning unit 100 may, in order to express 12-dimensional input data as a first anomaly feature to an n^{th} feature (e.g., n=2) on an n-dimensional plane (e.g., n=2), determine the most implicit n nodes (e.g., n=2) in a deep learning layer as anomaly feature extraction nodes (a first anomaly feature extraction node and a second anomaly feature extraction node).

In order for the anomaly feature extraction nodes to contain anomaly information, the deep learning model used in the present invention may be trained with input data that is assigned state information of a device as a constraint.

Hereinafter, a method of performing deep learning according to an embodiment of the present invention is described in detail.

A first anomaly feature and a second anomaly feature may be determined based on a first anomaly feature extraction node and a second anomaly feature extraction node, respectively.

The anomaly plane generating unit 110 may be implemented to generate an n-dimensional space for determining the state of a device. For example, the anomaly plane generating unit 110 may generate a two-dimensional anomaly plane based on a first anomaly feature and a second anomaly feature. State indicator data for each state of the device may be located on the anomaly plane based on the first anomaly feature and the second anomaly feature corresponding to the state indicator data.

For example, the existing 12-dimensional input data about the state of a transformer may be converted into state indicator data having a first anomaly feature and a second anomaly feature, and the state indicator data may be located on the anomaly plane.

A decision boundary may be generated on the anomaly plane to determine the state of a device. For example, when the device is a transformer as in the present invention, a support vector machine (SVM) technique may be applied to state indicator data corresponding to five transformer states of normal (blue), caution (green), warning (yellow), critical (orange), and fault (red), and accordingly, a decision boundary for classifying the states of the transformer may be determined.

Based on newly input target input data of a target device for determination, the target device may be subject to state determination on the anomaly plane.

The input unit 120 may receive the target input data of the target device for determination. For example, when it is desired to determine a state of a transformer, which is a determination target, 12-dimensional input data of the transformer may be input as target input data.

The anomaly feature extracting unit 130 may input the target input data into a deep learning model to extract a first anomaly feature and a second anomaly feature of the target input data, and state indicator data (target input data) of the target input data may be determined based on the first anomaly feature and the second anomaly feature.

The anomaly indicator determining unit 140 may be implemented to determine the anomaly indicator of the state indicator data (target input data).

When the state indicator data (target input data) is not adjacent to the decision boundary on the anomaly plane, the anomaly indicator of the state indicator data (target input data) may be determined to correspond to an area to which the state indicator data (target input data) belongs.

Conversely, when the state indicator data (target input data) is located in a boundary area adjacent to the decision boundary on the anomaly plane, the anomaly indicator of the state indicator data (target input data) may be determined by additionally considering the anomaly indicators of a plurality of pieces of adjacent state indicator data that are adjacent to the state indicator data (target input data).

The device state determining unit 150 may determine the state of a device (e.g., a transformer) based on an anomaly indicator of the device determined through the anomaly indicator determining unit 140.

The processor 160 may be implemented to control operations of the deep learning unit 100, the anomaly plane generating unit 110, the input unit 120, the anomaly feature extracting unit 130, the anomaly indicator determining unit 140, and the device state determining unit 150.

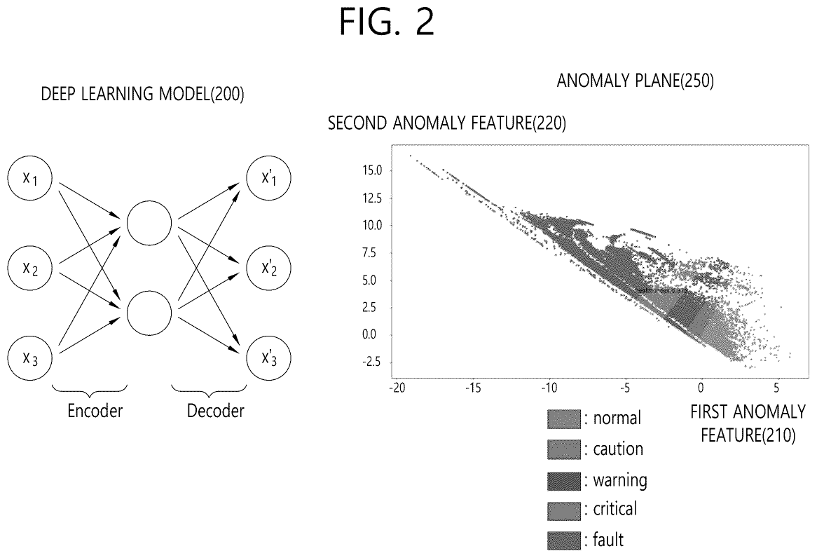

FIG. 2 discloses a method of generating an anomaly plane for determining the state of a device according to an embodiment according to the present invention.

In FIG. 2, a method of generating an anomaly plane for extracting an anomaly indicator of a device is disclosed.

Referring to FIG. 2, an anomaly plane 250 is a plane composed of two anomaly features (a first anomaly feature 210 and a second anomaly feature 220) extracted by learning 12-dimensional input data of gas concentrations of six types of dissolved gases, H₂, C₂H₂, CH₄, C₂H₄, C₂H₆, and CO, and a composition ratio of the dissolved gases (specific dissolved gas concentration/total dissolved gas concentration).

In order to determine the anomaly plane 250, deep learning may be performed.

A deep learning model 200 used in the present invention is a neural network model that copies information, such as input data, into output data, and may be used for data restoration or data compression.

Deep learning to determine the anomaly plane 250 may perform a method of setting various constraints depending on the purpose to prevent simple copying of input data, and efficiently expressing the characteristics of the input data through the setting of the constraints. Through the deep learning process, each node present between an encoder and a decoder may implicitly contain the characteristics of the input information.

In the present invention, in order to express 12-dimensional input data as a first anomaly feature to an n^{th} anomaly feature (e.g., n=2) on an n-dimensional plane (e.g., n=2), the most implicit n nodes (e.g., n=2) (a first anomaly feature extraction node 260 and a second anomaly feature extraction node 270) in the deep learning layer may be extracted.

Hereinafter, for convenience of description, the anomaly plane 250 is two-dimensional, and a method of determining a first anomaly feature 210 and a second anomaly feature 220 through two nodes is disclosed. However, the dimension of the anomaly plane, the number of anomaly features, and the number of anomaly feature extraction nodes may be changed, and the corresponding embodiments may also be included within the scope of the present invention.

For example, 12-dimensional input data input for deep learning may be data regarding each of six types of insulating oil gases (H₂, C₂H₂, CH₄, C₂H₄, C₂H₆, and CO) and data regarding each of the composition ratios of the six types of insulating oil gases (corresponding gas concentration/total concentration).

The deep learning model used in the present invention may be trained with input data that is assigned state information as a constraint such that the anomaly feature extraction nodes 260 and 270 contain anomaly information. An anomaly plane may be determined through the first anomaly feature extraction node 260 and the second anomaly feature extraction node 270 learned based on the constraint.

On the anomaly plane 250, state indicator data having the first anomaly feature 210 and the second anomaly feature 220 corresponding to the input data as coordinates may be located. An SVM may be applied to five transformer states of normal (blue), caution (green), warning (yellow), critical (orange), and fault (red) corresponding to state indicator data, and accordingly, a decision boundary for determining the state of the transformer may be determined.

After the training of the deep learning model as described above, when a first anomaly feature and a second anomaly feature of state indicator data (target input data) corresponding to target input data, which is input to determine the state of a transformer, are far away from the decision boundary on the anomaly plane and located outside the boundary area, the state of the transformer may correspond to an area (an anomaly indicator of an area classified based on an SVM) classified based on an SVM.

Conversely, when a first anomaly feature and a second anomaly feature of state indicator data (target input data) corresponding to target input data input to determine the state of a transformer are located in the boundary area adjacent to the decision boundary on the anomaly plane, the method of determining the state of the transformer based on the target input data may be uncertain in identifying an area among the areas classified by the SVM to which the state corresponds.

Therefore, according to the present invention, a decision boundary of the states of a transformer may be determined based on an SVM, but when state indicator data (target input data) input for determining the state of a transformer is located in a boundary area based on the decision boundary, the anomaly indicator of the data located in the boundary area may be determined through additional state classification, and the state of the transformer may be more specifically determined through the anomaly indicator.

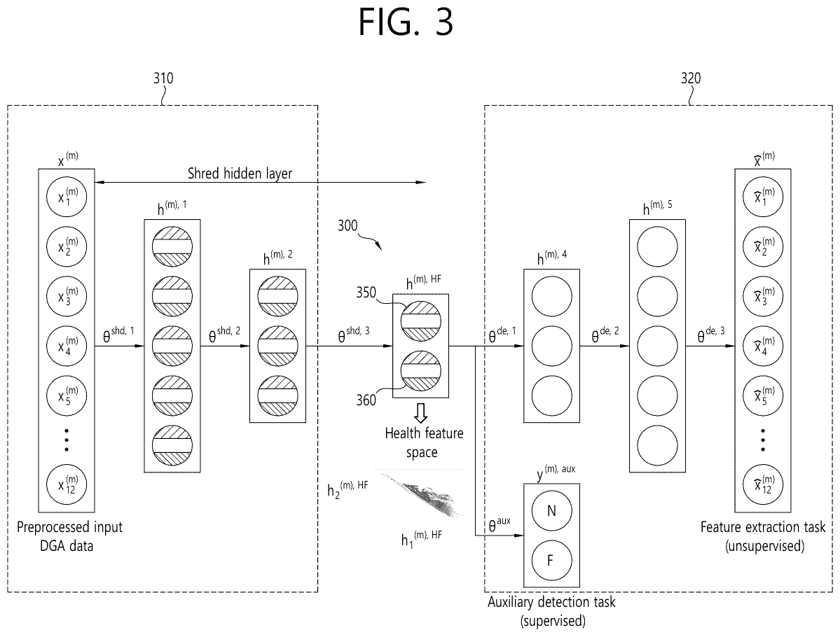

FIG. 3 is a conceptual diagram showing a method of determining a first anomaly feature and a second anomaly feature according to an embodiment according to the present invention.

In FIG. 3, a method of determining two anomaly feature extraction nodes for determining a first anomaly feature and a second anomaly feature is disclosed.

Referring to FIG. 3, the two anomaly feature extraction nodes 300 may be determined through training by a deep learning algorithm.

In an embodiment according to the present invention, incoming input data passes through a plurality of layers of the deep learning model, and duplicate data is generated as output data. In this case, since the outputs of the layers are typically hidden, the layers are referred to as hidden layers, and the layers are composed of nodes h(m). The number of nodes and layers for deep learning is a parameter set by the user and may usually be determined through optimization.

The role of a layer is to calculate the weight values of each node for replicating a previous input value.

In the deep learning model according to the embodiment according to the present invention, a replication value may be calculated through the function y=fθ(x)=s(Wx+b) when 12-dimensional input data based on a concentration of dissolved gas is given as an input value.

Function s is an activation function, and a model with the best performance may be selected depending on the data.

W in the above function is a weight vector and a characteristic value that is given to each node. The deep learning model according to the present invention may learn the node weight through iterative optimization such that the error between an input value and an output value is minimized.

In particular, the deep learning model according to the present invention may be a model in which a plurality of hidden layers overlap as shown in FIG. 2, and have a left-right symmetrical structure with respect to a central layer 300 located in the center. A first layer group 310 located on the left with respect to the central layer 300 performs compression on the input data, and a second layer group 320 located on the right with respect to the central layer 300 performs decompression on the input data. Such compression and decompression of the input data leads to the generation of output data, and the output data may be data that replicates the input data.

Therefore, in a layer structure according to the present invention, a node value corresponding to the central layer 300 located in the center contains the most critical information, and in order to generate an anomaly plane that is a two-dimensional plane having a first anomaly feature and a second anomaly feature as both axes according to the present invention, the central layer 300 is set as two nodes.

The two nodes included in the central layer 300 correspond to a first anomaly feature extraction node 350 and a second anomaly feature extraction node 360. Through the weight values of the two nodes located in the central layer 300, that is, the first anomaly feature extraction node 350 and the second anomaly feature extraction node 360, the first anomaly feature and the second anomaly feature constituting the X and Y axes forming the anomaly plane may be determined.

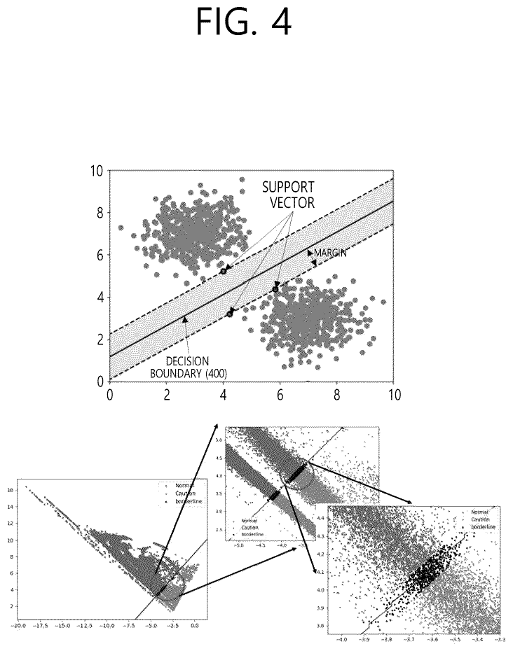

FIG. 4 discloses a method of classifying a transformer state based on an SVM according to an embodiment of the present invention.

Referring to FIG. 4, an SVM is a model for finding a decision boundary 400 between classes when a plurality of classes of data are present. SVMs are widely used in various data classification problems, and a class to which arbitrary data belongs may be determined based on the decision boundary 400 determined by an SVM.

An SVM algorithm is performed based on support vectors and a margin. The support vector is data located closest to the decision boundary 400 and may be a criterion for calculating a margin. A margin may refer to the distance between the decision boundary 400 and a support vector. An SVM may derive an optimal classification model by searching for the decision boundary 400 where the margin is maximized.

The existing state indicator data for each of five previously obtained transformer states (normal (blue), caution (green), warning (yellow), critical (orange), and fault (red)) may be located on the anomaly plane described above.

The existing state indicator data for each of the five transformer states may be classified based on the support vector and the margin described above.

After the existing state indicator data is subject to state classification based on the SVM, in the case of state indicator data located in the boundary area adjacent to the decision boundary 400, there may be a difficulty in determining the state of the transformer based on the state indicator data.

In the present invention, when state indicator data (target input data) is located in the boundary area, an additional data classification algorithm may be used to determine the state of the transformer based on the state indicator data (target input data).

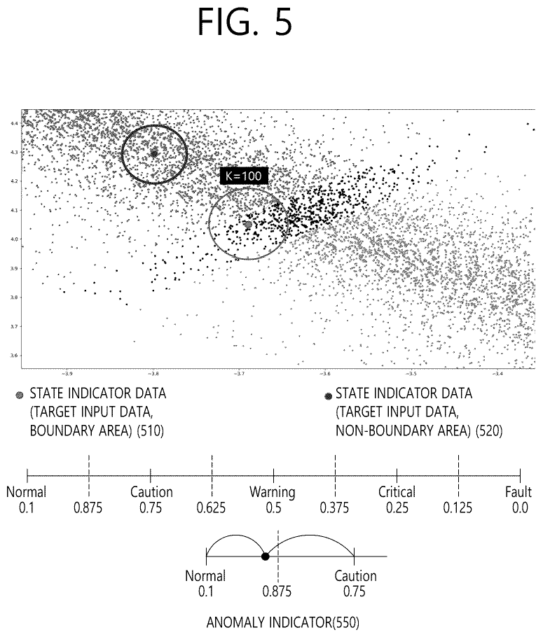

FIG. 5 is a conceptual diagram showing a method of determining the state of a transformer through additional data classification for state indicator data (target input data) located in the boundary area according to an embodiment of the present invention.

In FIG. 5, a method of determining the state of a transformer corresponding to state indicator data (target input data) in the boundary area through additional data classification is disclosed.

Referring to FIG. 5, the decision boundary between specific transformer states (normal-caution) divided using an SVM is disclosed.

State indicator data adjacent to the decision boundary may be expressed as state indicator data (target input data, boundary area) 510.

The state indicator data (target input data, boundary area) 510 may be data in which a critical number (e.g., 100) of different pieces of state indicator data, which are adjacent to the data based on the position on the anomaly plane, do not correspond to the same transformer state.

That is, when 100 pieces of state indicator data located around specific state indicator data (target input data) correspond to a normal state, the specific state indicator data may be state indicator data (target input data, non-boundary area) 520 and correspond to a normal state.

Conversely, when 100 pieces of state indicator data located around specific state indicator data (target input data) correspond to different states, that is, a normal state and a caution state, the specific state indicator data (target input data) may be determined as state indicator data (target input data, boundary area) 510, and the transformer state may be determined through additional data classification.

Specifically, in order to determine the transformer state corresponding to the state indicator data (target input data, boundary area) 510, a critical number (e.g., 100) of pieces of state indicator data centered on the state indicator data (target input data, boundary area) 510 may be determined.

The extracted critical number (e.g., 100) of pieces of state indicator data centered on the state indicator data (target input data, boundary area) 510 may be expressed as state indicator data (extraction).

Based on the ratios of the plurality of pieces of indicator data (extraction), the state of the state indicator data (target input data, boundary area) 510 may be determined. For example, it may be assumed that 100 pieces of state indicator data (extraction) centered on state indicator data (target input data, boundary area) 510 include 60 pieces of state indicator data (extraction) corresponding to a normal state and 40 pieces of state indicator data (extraction) corresponding to a caution state.

When the anomaly indicator 550 has a value of 1 for a normal state and 0.75 for a caution state, a point between 1 and 0.75 divided by a ratio of 4 to 6 may be the anomaly value of the state indicator data (target input data, boundary area) 510. In this case, it may be determined that the state of the transformer corresponding to the state indicator data (target input data, boundary area) 510 is normal with a probability of 60%. In this case, when the anomaly indicator 550 has a value greater than 0.875, which is the intermediate value between the anomaly value of the normal state and the anomaly value of the caution state, the state of the transformer corresponding to the state indicator data (target input data, boundary area) 510 may be determined as being normal.

As described above, it is possible to more accurately determine the state of the transformer based on the state indicator data (target input data) located in the boundary area.

The embodiments of the present invention described above may be implemented in the form of program instructions that can be executed through various computer units and recorded on computer readable media. The computer readable media may include program instructions, data files, data structures, or combinations thereof. The program instructions recorded on the computer readable media may be specially designed and prepared for the embodiments of the present invention or may be available instructions well known to those skilled in the field of computer software. Examples of the computer readable media include magnetic media such as a hard disk, a floppy disk, and a magnetic tape, optical media such as a compact disc read only memory (CD-ROM) and a digital video disc (DVD), magneto-optical media such as a floptical disk, and a hardware device, such as a ROM, a RAM, or a flash memory, that is specially made to store and execute the program instructions. Examples of the program instruction include machine code generated by a compiler and high-level language code that can be executed in a computer using an interpreter and the like. The hardware device may be configured as at least one software module in order to perform operations of embodiments of the present invention and vice versa.

While the present invention has been described with reference to specific details such as detailed components, specific embodiments and drawings, these are only examples to facilitate overall understanding of the present invention and the present invention is not limited thereto. It will be understood by those skilled in the art that various modifications and alterations may be made.

Therefore, the spirit and scope of the present invention are defined not by the detailed description of the present invention but by the appended claims, and encompass all modifications and equivalents that fall within the scope of the appended claims.

What is claimed is:

1. A method of determining an anomaly indicator through machine learning, the method comprising:
determining, by a device state determining apparatus, anomaly features based on machine learning;
generating, by the device state determining apparatus, an anomaly plane based on the anomaly features;
receiving, by the device state determining apparatus, target input data of a target device;
determining, by the device state determining apparatus, an anomaly indicator corresponding to the target input data based on the anomaly plane; and
determining, by the device state determining apparatus, a state of the target device based on the anomaly indicator.

2. The method of claim 1, wherein the anomaly plane includes a plurality of pieces of state indicator data determined based on the machine learning, and
the plurality of pieces of state indicator data are classified based on a decision boundary.

3. The method of claim 2, wherein the device state determining apparatus determines the state of the target device based on the decision boundary and a location of state indicator data (target input data) corresponding to the target input data on the anomaly plane.

4. A device state determining apparatus, which is an apparatus for determining an anomaly indicator through machine learning, the apparatus comprising:
a deep learning unit implemented to determine anomaly features based on machine learning;
an anomaly plane generating unit configured to generate an anomaly plane based on the anomaly features;
an input unit implemented to receive target input data of a target device;
an anomaly indicator determining unit implemented to determine an anomaly indicator corresponding to the target input data based on the anomaly plane; and
a device state determining unit implemented to determine a state of the target device based on the anomaly indicator.

5. The apparatus of claim 4, wherein the anomaly plane includes a plurality of pieces of state indicator data determined based on the machine learning, and
the plurality of pieces of state indicator data are classified based on a decision boundary.

6. The apparatus of claim 5, wherein the anomaly indicator determining unit determines the anomaly indicator based on the decision boundary and a location of state indicator data (target input data) corresponding to the target input data on the anomaly plane.
